(19) United States
(12) Patent Application Publication
(10) Pub. No.: US 2023/0051536 A1
(43) Pub. Date: Feb. 16, 2023

(54) DISPLAY SUBSTRATE AND DISPLAY APPARATUS

(71) Applicant: BOE TECHNOLOGY GROUP CO., LTD., Beijing (CN)

(72) Inventors: Hongwei TIAN, Beijing (CN); Yanan NIU, Beijing (CN); Bingwei WANG, Beijing (CN); Hejin WANG, Beijing (CN); Yang YU, Beijing (CN); Zheng LIU, Beijing (CN)

(21) Appl. No.: 17/789,429

(22) PCT Filed: Sep. 1, 2021
(86) PCT No.: PCT/CN2021/115876

§ 371 Date: Jun. 27, 2022

(30) Foreign Application Priority Data
Oct. 21, 2020 (CN) 202011132725.8

(51) Int. Cl. H01L 51/00; H01L 27/32; B32B 3/26; B32B 3/30

(52) U.S. Cl. CPC H01L 51/0097; H01L 27/3276; B32B 3/266; B32B 3/30; H01L 2251/5338; B32B 3/04

(57) ABSTRACT

The present disclosure provides a display substrate and a display apparatus, belonging to the field of display technology. The present disclosure provides a display substrate, having a plurality of island regions, bridge regions and clearance regions. The display substrate includes: at least one base including a sub-base and a buffer layer. The sub-base includes a first surface and a second surface opposite to each other, and the buffer layer is disposed on a side of the second surface of the sub-base away from the first surface. In the at least one base, the sub-base of any base has a same orientation. At least one first opening is provided at a position of the buffer layer of the at least one base corresponding to each island region.

### TECHNICAL FIELD

The present disclosure belongs to the field of display, and specifically relates to a display substrate and a display apparatus.

### BACKGROUND

With the advancement of technology, in recent years, full-screen display has gradually come into view. Organic electroluminescent display panels (OLEDs) have become mainstream products in the display field due to their characteristics of self-luminescence, high brightness, high contrast, low operating voltage, capability of being manufactured as flexible displays, and the like.

Display panels includes flexible display panels and rigid display panels. The flexible display panel includes a flexible base, and a buffer layer on the flexible base. When an external force is applied to stretch the flexible display panel, cracks will appear, due to a limited stretching amount, at positions of the buffer layer where the stress is concentrated, resulting in damage to the display panel. The rigid display panel includes a rigid base, and a buffer layer on the rigid base. In regions of the rigid display panel where the stress is concentrated, such as corners, the stretching amount of the buffer layer is limited under a relatively high stress. As a result, cracks may occur at portions of the buffer layer corresponding to the corners, resulting in damage to the display panel.

### SUMMARY

To solve at least one of the problems in the existing art, the present disclosure provides a display substrate that can avoid increasing the stretchable amount of the display substrate, and prevent cracks in the buffer layer of the display substrate due to stretching and damage to the display substrate.

In a first aspect, an embodiment of the present disclosure provides a display substrate, having a plurality of island regions, bridge regions and clearance regions, the bridge regions are disposed around the island regions; and the display substrate includes:
at least one base including a sub-base and a buffer layer, where the sub-base includes a first surface and a second surface opposite to each other, and the buffer layer is disposed on a side of the second surface of the sub-base away from the first surface; and in the at least one base, the sub-base of any base has a same orientation;
a plurality of sub-pixels on a side of the buffer layer of an outermost base of the at least one base away from the sub-base of the outermost base, each sub-pixel including a light-emitting device and a pixel circuit; where each island region is provided with at least one sub-pixel; and
a plurality of signal lines connected to the pixel circuit; where the plurality of signal lines are distributed in the bridge regions;
wherein
the buffer layer of the at least one base has at least one first opening is provided at a position of the buffer layer corresponding to the island region.

In the display substrate provided in the embodiments of the present disclosure, since a second opening is provided in the buffer layer of the at least one base of the display substrate, the stretchability of the buffer layer can be increased, and cracks in the buffer layer due to stretching can be avoided, thereby avoiding damage to the display substrate.

In some examples, the first opening includes a plurality of first sub-openings and a plurality of second sub-openings arranged at intervals along a first direction, and
an extending direction of the plurality of first sub-openings intersects with an extending direction of the plurality of second sub-openings.

In some examples, the plurality of first sub-openings are connected to the plurality of second sub-openings to form the first opening, and the first opening has a first side and a second side opposite to each other in the first direction;
the first side has a plurality of first peaks and a plurality of first valleys; and the second side has a plurality of second peaks and a plurality of second valleys;
the first peaks and the second valleys are arranged in one-to-one correspondence, and the second peaks and the first valleys are arranged in one-to-one correspondence; and
any one of the first peaks is close to a second valley between two second peaks on two sides of the first peak, with respect to a connection line between the two second peaks.

In some examples, the first opening includes one third sub-opening and a plurality of fourth sub-openings; the third sub-opening extends in a first direction, and the plurality of fourth sub-openings extend in a second direction intersecting with the first direction; and
the plurality of fourth sub-openings are connected to the third sub-opening, and arranged in the first direction.

In some examples, the first opening includes a plurality of fifth sub-openings extending in a same direction and arranged in a first direction.

In some examples, the first opening includes a plurality of sixth sub-openings, each of which includes a first bent section and a second bent section bent in opposite directions, and a second end of the first bent section is connected to the first end of the first bent section;
for two adjacent sixth sub-openings, a connection line between an end of the first bent section and an end of the second bent section of one sixth sub-opening passes through the first bent section of the other sixth sub-opening.

In some examples, the pixel circuits include a plurality of transistors, and orthographic projections of the plurality of transistors on the buffer layer do not overlap the first opening.

In some examples, the first opening penetrates a corresponding buffer layer;
or, the first opening has a depth less than half a thickness of the corresponding buffer layer.

In some examples, the display substrate further includes:
at least one inorganic film layer laminated with the buffer layer of the outermost base of the at least one base, where the at least one inorganic film layer has at least one second opening provided at a position of the at least one inorganic film layer corresponding to the island region.

In some examples, an orthographic projection of the second opening on the buffer layer has an overlap region with the first opening.

In some examples, the second opening and the first opening are provided in one-to-one correspondence, and have a same shape.

In some examples, the second opening penetrates a corresponding inorganic film layer;
or, the second opening has a depth less than half a thickness of the corresponding inorganic film layer.

In some examples, the sub-base of any one of the at least one base is a flexible base; the at least one base includes a first base and a second base, the first base includes a first sub-base and a first buffer layer, and the second base includes a second sub-base and a second buffer layer; and
a thickness of the second sub-base is 40% to 60% of a thickness of the first sub-base.

In some examples, the base is a rigid base having corner regions, and the island regions, the bridge regions and the clearance regions are provided in only the corner regions.

In a second aspect, an embodiment of the present disclosure further provides a display apparatus including the display substrate as described above.

### BRIEF DESCRIPTION OF DRAWINGS

FIG. 1a is a schematic planar structure view of an embodiment of a display substrate according to an embodiment of the present disclosure (a rigid display substrate).

FIG. 1b is a schematic planar structure view of an embodiment of a display substrate according to an embodiment of the present disclosure (a flexible display substrate).

FIG. 2 is a schematic diagram of partial partition distribution of an embodiment of a display substrate according to an embodiment of the present disclosure.

FIG. 3 is a sectional view (along direction A-B in FIG. 2) of an embodiment of a display substrate according to an embodiment of the present disclosure.

FIG. 4 is a sectional view (a double-layer base) of an embodiment of a display substrate according to an embodiment of the present disclosure.

FIG. 5 is a sectional view of an embodiment of a display substrate according to an embodiment of the present disclosure, in which the first opening does not penetrate through the buffer layer).

FIG. 6 is a first schematic structural diagram of an embodiment of the first opening in the display substrate according to an embodiment of the present disclosure.

FIG. 7 is a detailed schematic structural diagram of an embodiment of the first opening in the display substrate according to an embodiment of the present disclosure.

FIG. 8 is a second schematic structural diagram of an embodiment of the first opening in the display substrate according to an embodiment of the present disclosure.

FIG. 9 is a third schematic structural diagram of an embodiment of the first opening in the display substrate according to an embodiment of the present disclosure.

FIG. 10 is a fourth schematic structural diagram of an embodiment of the first opening in the display substrate according to an embodiment of the present disclosure.

FIG. 11 is a circuit diagram of an embodiment of a pixel circuit in a display substrate according to an embodiment of the present disclosure.

FIG. 12 is a positional relationship diagram of transistors of the pixel circuit and the first opening in a display substrate according to an embodiment of the present disclosure.

FIG. 13 is a sectional view of an embodiment of a display substrate according to an embodiment of the present disclosure.

FIG. 14 is a positional relationship diagram of the first opening and a second opening in a display substrate according to an embodiment of the present disclosure.

FIG. 15 is a first sectional view of an embodiment of a base and an encapsulation layer in a display substrate according to an embodiment of the present disclosure.

FIG. 16 is a second sectional view of an embodiment of a base and an encapsulation layer in a display substrate according to an embodiment of the present disclosure.

### DETAIL DESCRIPTION

To make the objects, technical solutions and advantages of the present disclosure clearer, the present disclosure will be described in further detail with reference to the accompanying drawings, and it is apparent that the described embodiments are only some, but not all, embodiments of the present disclosure. Based on the embodiments of the present disclosure, all other embodiments obtained by those ordinary skilled in the art without any creative effort fall into the protection scope of the present disclosure.

The shapes and sizes of the components in the drawings are not necessarily drawn to scale, but are merely intended to facilitate understanding of the contents of the embodiments of the present disclosure.

Unless otherwise defined, technical or scientific terms used in the present disclosure are intended to have general meanings as understood by those of ordinary skill in the art. The words “first”, “second” and similar terms used in the present disclosure do not denote any order, quantity, or importance, but are used merely for distinguishing different components from each other. Also, the use of the terms “a”, “an”, “the” or a similar referent does not denote a limitation of quantity, but rather denotes the presence of at least one element. The word “comprising”, “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, or the like are merely used to indicate a relative positional relationship, and when an absolute position of the described object is changed, the relative positional relationship may also be changed accordingly.

The transistors used in the embodiments of the present disclosure may be thin film transistors or field effect transistors or other devices with same characteristics, and since the source and the drain of the transistor adopted are exchangeable under certain conditions, there is no difference between the source and the drain in terms of description of the connection relationship. In the embodiments of the present disclosure, to distinguish the source and the drain of a transistor, one of the source and the drain is referred to as a first electrode, the other is referred to as a second electrode, and the gate is referred to as a control electrode. In addition, the transistors may be divided into N-type transistors and P-type transistors according to the characteristics of the transistors. The following embodiments are explained taking the case where each transistor is a P-type transistor as an example. When a P-type transistor is adopted, the first electrode refers to the source of the P-type transistor, the second electrode refers to the drain of the P-type transistor, and when a low level is input at the gate, the source and the drain are conducted. For an N-type transistor, the opposite case is applied. It is conceivable that the implementation with N-type transistors can be easily conceived by those skilled in the art without any creative effort, and therefore, also falls into the scope of the embodiments of the present disclosure.

It should be noted that the transistors used in the embodiments of the present disclosure may be thin film transistors or field effect transistors or other switch devices with same characteristics, and the thin film transistors may include oxide semiconductor thin film transistors, amorphous silicon thin film transistors, or polysilicon thin film transistors, etc.

The embodiments of the present disclosure are not limited to the embodiments shown in the drawings, but include modifications of configurations formed based on a manufacturing process. Thus, the regions illustrated in the figures have schematic properties, and the shapes of the regions shown in the figures illustrate specific shapes of regions of elements, but are not intended to be limitative.

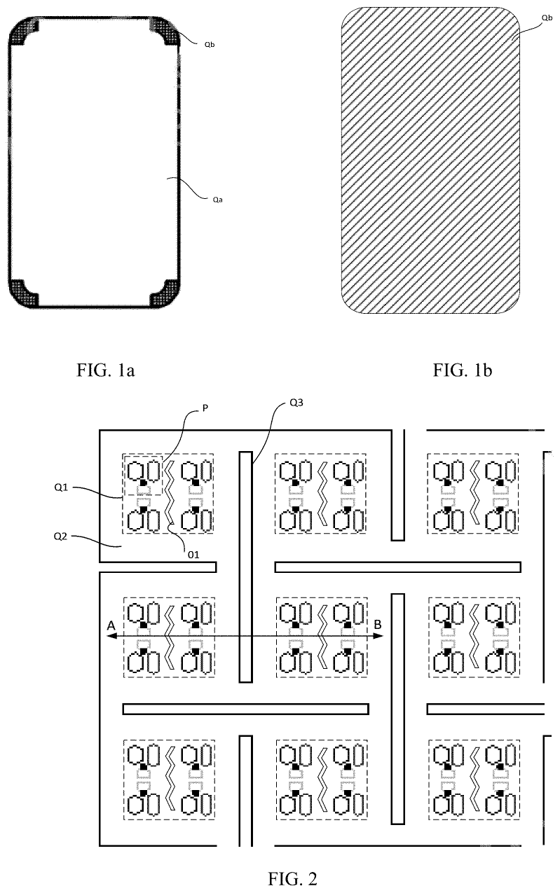

The display substrate provided in the embodiment of the present disclosure may be a flexible display substrate or a rigid display substrate. Referring to FIGS. 1a and 1b, FIG. 1a illustrates a schematic structural diagram of a rigid display substrate, FIG. 1b illustrates a schematic structural diagram of a flexible display substrate, and the display substrates shown in FIGS. 1a and 1b may be used in a full-screen display apparatus. As shown in FIG. 1, the display substrate includes a main display region Qa, and stretchable regions Qb located at corners of the display substrate. Since the rigid display substrate has a small stretching amount, the stress is concentrated in some regions, such as the corners. In this embodiment, the case where the four corners are stretchable regions Qb is taken as an example for description. As shown in FIG. 2, since the entire display region of a flexible display panel is stretchable or bendable, the entire display region is a stretchable region Qb. That is, the stretchable region Qb may be a partial region of the display substrate, or may be the entire display region of the display substrate. The island regions, bridge regions, and clearance regions of the display substrate in the embodiment of the present disclosure are all applied in the stretchable region Qb to prevent the display substrate from being damaged due to excessive stretching. However, it will be appreciated that the display substrate in the embodiment of the present disclosure is not limited to a rectangular shape, but may have any other shape such as a circular shape, a hexagonal shape or the like. The stretchable area Qb is not limited to a corner of the display substrate.

In a first aspect, as shown in FIG. 2, an embodiment of the present disclosure provides a display substrate, having a plurality of island regions Q1, bridge regions Q2 and clearance regions Q3. FIG. 2 shows a schematic distribution diagram of the regions on the display substrate. The clearance regions Q3 are disposed around the island regions Q1, and the regions between the clearance regions Q3 and the island regions Q1 define the bridge regions Q2. In order to release the stress generated by stretching and avoid damage to the display substrate when the display substrate is stretched, substrate openings are provided in a substrate (including at least one base) of the display substrate, and regions where the substrate openings are located are the clearance regions Q3. The display substrate includes a plurality of sub-pixels P. Each island region Q2 is provided with at least one sub-pixel P, and the sub-pixel P has a light-emitting device and a pixel circuit connected to the light-emitting device to drive the light-emitting device to emit light. The display substrate further has a plurality of signal lines. The plurality of signal lines are arranged in the bridge regions Q3, and enter the island regions Q1 from the bridge regions Q12, to provide driving signals for the pixel circuits in the island regions Q1. The pixel circuit and the signal line will be described in detail later.

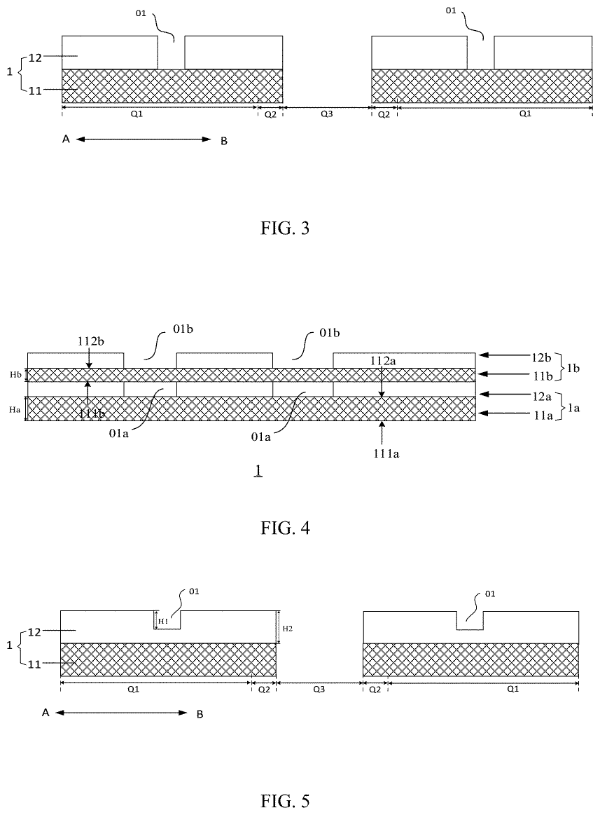

Further, as shown in FIGS. 2 to 4, the display substrate provided in the embodiment of the present disclosure includes at least one base 1. That is, the display substrate may use a single-layer base or a multilayer base as the substrate. Referring to FIG. 3, which is a sectional view of an example of the display substrate using a single-layer base as the substrate along the direction A-B in FIG. 1, in a case where the display substrate uses a single-layer base as the substrate, the display substrate includes one sub-base 11 and a buffer layer 12 on the sub-base 11. In a case where the display substrate uses multi layers of bases as the substrate, multiple layers of bases are stacked, and each layer of base 1 includes a sub-base 11 and a buffer layer 12. The sub-base 11 includes a first surface and a second surface opposite to each other, and the buffer layer 12 is disposed on a side of the second surface of the sub-base 11 away from the first surface. Further, sub-bases 11 of the bases 1 in the multilayer base have a same orientation. In other words, first surfaces of the sub-bases 11 are oriented to a same direction, and for the sub-bases 11 of two adjacent bases 1, the first surface of one base is always opposite to the second surface of the other base, and a sub-base 11 is always provided between buffer layers 12 of the two adjacent bases 1. For example, referring to FIG. 4, which shows a sectional view of an example of a display substrate using double layers of bases, the display substrate includes a first base 1a and a second base 1b. The first base 1a includes a first sub-base 11a and a first buffer layer 12a. The first sub-base 11a includes a first surface 111a (the lower surface in the figure) and a second surface 112a (the lower surface in the figure) opposite to each other. The first buffer layer 12a is disposed on a side of the second surface 112a of the first sub-base 11a away from the first surface 111a. The second base 1b includes a second sub-base 11b and a second buffer layer 12b. The second sub-base 11b includes a first surface 111b (the lower surface in the figure) and a second surface 112b (the lower surface in the figure) opposite to each other. The second buffer layer 12b is disposed on a side of the second surface 112b of the second sub-base 11b away from the first surface 111b. The first base 1a and the second base 1b are stacked to form the substrate of the display substrate, and the first base 1a and the second base 1b have a same orientation. That is, the first base 1a is arranged in a direction in which the first surface 111a of the first base 1a points to the second surface 112a, and the second base 1b is arranged in a direction in which the first surface 111b of the second base 1b points to the second surface 112b. The display substrate further includes a plurality of sub-pixels P on a side of the second buffer layer 12b of the second base 1b away from the first base 1a. Obviously, the display substrate may further include more layers of bases 1, which are not specifically limited here.

In some examples, the base 1 may be a flexible base or a rigid base. In a case where the base 1 is a flexible base and the display substrate includes multiple layers of bases 1, sub-bases 11 in different bases 1 may differ in thickness to avoid an excessive stack thickness of the multiple layers of bases 1 and prevent the display substrate from being difficult to bend. For example, referring to FIG. 4, taking the case where the display substrate includes a first base 1a and a second base 1b as an example, the first base 1a is provided under the second base 1b, and a thickness Hb of the second sub-base 11b of the second base 1b may be smaller than a thickness Ha of the first sub-base 11a of the first base 1a. Specifically, the thickness Hb of the second sub-base 11b is 40% to 60% of the thickness Ha of the first sub-base 11a. For example, if the thickness Ha of the first sub-base 11a is 1000 angstroms, the thickness of the second sub-base 11b may be between 400 and 600 angstroms.

Further, the number of sub-pixels P in each island region Q1 of the display substrate may be set as needed, and each island region Q1 may be provided with one sub-pixel P or a plurality of sub-pixels P. FIG. 2 takes the case where each island region Q1 includes 4 sub-pixels P as an example for description. If too many sub-pixels P are provided in each island region Q1, there will be fewer clearance regions Q3, making the display substrate insufficient in stress release and easy to be damaged due to stretching. If too few sub-pixels P are provided in each island region Q1, there will be more clearance regions Q3, i.e., more substrate openings penetrating at least one layer of base 1 of the entire base, resulting in a relatively low strength of the substrate such that cracks are easy to be generated due to stretching, causing damage to the display substrate.

In order to solve the above problems, as shown in FIGS. 2 and 3, in the display substrate provided in the embodiments of the present disclosure, the buffer layer 12 of the at least one base 1 of the display substrate has at least one first opening 01 at a position of the buffer layer 12 corresponding to each island region Q1. The buffer layer 12 is typically made of an inorganic material, such as silicon oxide, silicon nitride, or the like, so as to achieve the effect of blocking water, oxygen and alkali ions. Therefore, the buffer layer 12 has relatively high hardness and large thickness. When the display substrate is stretched, the buffer layer 12 is hard to be stretched, and has a relatively high stress. Therefore, cracks are easy to be generated especially at edges of the buffer layer 12 corresponding to the bridge regions Q2 and the clearance regions Q3. If too many cracks are generated, the buffer layer 12, and thus the display substrate, will be damaged. In the display substrate provided in the embodiments of the present disclosure, since a first opening 01 is provided in the buffer layer 12 of the at least one base 1 of the display substrate, the stress accumulated on the buffer layer 12 during stretching can be released, thereby avoiding cracks in the buffer layer 12 due to stretching, as well as damage to the display substrate. Moreover, the first opening 01 in the buffer layer 12 can increase stretchability of the buffer layer 12, so that the stretchability of the display substrate in which the buffer layer 12 is provided is not affected.

In some examples, in a case where the display substrate uses multi layers of bases as the substrate, the first opening 01 may be provided in the buffer layer 12 of each base 1, or in the buffer layers 12 of some of the bases 1, which may be set according to the desired stretching amount. Referring to FIG. 3, the first opening 01 of any buffer layer 12 may penetrate through the buffer layer 12. Referring to FIG. 5, the first opening 01 of any buffer layer 12 may have a half-groove structure, that is, a depth H1 of the first opening 01 is less than a thickness H2 of the buffer layer 12 where the first opening 01 is located. Specifically, the depth H1 of the first opening 01 may be less than half of the thickness H2 of the buffer layer 12 corresponding to the first opening 01. For example, if the thickness H2 of the buffer layer 12 is 50 to 2000 angstroms, the depth of the first opening H1 may be less than 25 to 1000 angstroms, that is, H1<0.5×H2. If the first opening 01 penetrates through the buffer layer 12 where the first opening 01 is located, the stretching amount of the buffer layer 12 can be greatly increased. If the first opening 01 has a half-groove structure not penetrating through the buffer layer 12, it can ensure that the first opening 01 of the buffer layer 12 will not be excessively deformed when the display substrate is stretched, and a bottom of the film layer of the buffer layer 12 at the first opening 01 can provide extra strength to the buffer layer 12, thereby avoiding damage to the buffer layer 12 due to excessive deformation of the first opening 01.

In some examples, the number of first openings 01 in the buffer layer 12 at a position corresponding to each island region Q1 may vary. Each island region Q1 may have a plurality of first openings 01 or one first opening 01. For example, referring to FIG. 4, the display substrate includes double layers of bases, that is, a first base 1a and a second base 1b, a first buffer layer 12a of the first base 1a has two first openings 01a provided at the positions of the first buffer layer 12a corresponding to one island region Q1, and a second buffer layer 12b of the second base 1b has two second openings 01b provided at the positions of the second buffer layer 12b corresponding to one island region Q1. As another example, referring to FIG. 5, the display substrate includes one base 1 including a sub-base 11 and a buffer layer 12 on the sub-base 11, and the buffer layer 12 has one first opening 01a provided at a position of the buffer layer 12 corresponding to one island region Q1. Further, the shape of the first opening 01 may also vary, which will be illustrated below.

It should be noted that the first direction S1 and the second direction S2 below may be any two directions intersecting with each other. For example, the first direction S1 may be a column direction of the sub-pixels P arranged in an array in the display substrate, and the second direction S2 may be a row direction of the sub-pixels P arranged in an array in the display substrate. For convenience of description, the following explanation is made taking the case where the first direction S1 is the column direction, the second direction S2 is the row direction, and the first direction S1 and the second direction S2 are perpendicular or substantially perpendicular to each other as an example.

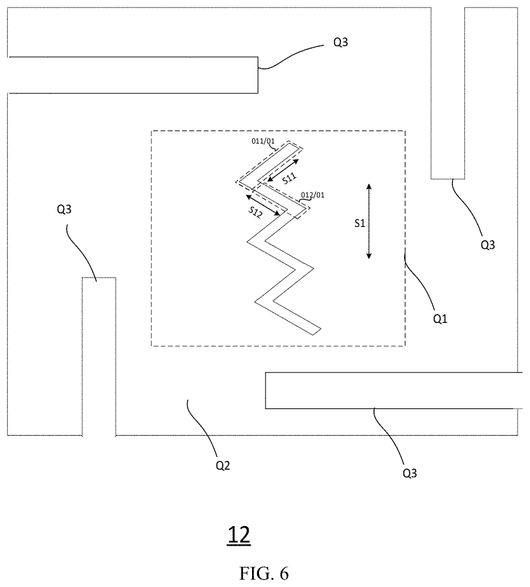

In some examples, referring to FIG. 6, taking the position of the buffer layer 12 corresponding to one island region Q1 as an example, one first opening 01a is provided in the buffer layer 12 at the position corresponding to one island region Q1. The first opening 01 includes a plurality of first sub-openings 011 and a plurality of second sub-openings 012 arranged at intervals along a first direction S1. That is, the plurality of first sub-openings 011 and the plurality of second sub-openings 012 are sequentially arranged in the first direction S1 to form the first opening 01 extending in the first direction S1, and each first sub-opening 011 is adjacent to a corresponding one of the second sub-openings 012. An extending direction of the plurality of first sub-openings 011 intersects with an extending direction of the plurality of second sub-openings 012. That is, the first sub-openings 011 and the second sub-openings 012 extend in different directions. For example, referring to FIG. 6, the plurality of first sub-openings 011 extend toward a first sub-direction S11, and the plurality of second sub-openings 012 extend toward a second sub-direction S12 not parallel to the first sub-direction S11. By providing the first opening 01 with sub-openings extending in different directions, continuous cracks on the first opening 01 in a unit direction is avoided, and the tear resistance of the buffer layer 12 is further enhanced. The first sub-openings 011 and the second sub-openings 012 may have various shapes. For example, the first sub-openings 011 and the second sub-openings 012 may be linear openings, or curved openings, or the like. For example, a plurality of linear first sub-openings 011 and second sub-openings 012 may be connected to form a substantially sawtooth-shaped first opening 01, and a plurality of curved first sub-openings 011 and second sub-openings 012 may be connected to form a substantially wave-shaped first opening 01. The specific shapes of the first sub-openings 011 and the second sub-openings 012 are not limited here, and in this embodiment, the case where the first sub-openings 011 and the second sub-openings 012 are both linear openings, and a plurality of linear first sub-openings 011 and second sub-openings 012 may be connected to form a substantially sawtooth-shaped first opening 01 is taken as an example for illustration.

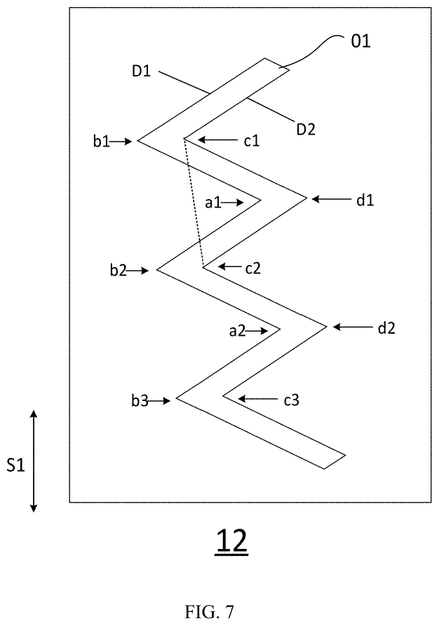

In some examples, referring to FIGS. 6 and 7, in which FIG. 7 is a schematic structural diagram of the first opening 01 in FIG. 6, the plurality of first sub-openings 011 are connected to the plurality of second sub-openings 012 to form the first opening 01. Taking a substantially sawtooth-shaped first opening 01 as an example, the first opening 01 has a first side D1 and a second side D2 opposite to each other in the first direction S1 (i.e., the extending direction of the first opening). In FIG. 7, the case where the first side D1 is a left edge of the first opening 01, and the second side 02 is a right edge of the first opening 01 is taken as an example for illustration. Since the first sub-openings 011 and the second sub-openings 012 extend in different directions, while the plurality of first sub-openings 011 are connected to the plurality of second sub-openings 012 to form the first opening 01, it will be appreciated that the first opening 01 is a substantially sawtooth-shaped opening having multiple bent line segments, and edges of the sawtooth-shaped opening have a plurality of convex parts and concave parts. Hereinafter, the convex parts are referred to as peaks, and the concave parts are referred to as valleys. Referring to FIG. 7, the first side D1 of the first opening 01 has a plurality of first peaks (a1 to a2 in FIG. 7) and first valleys (b1 to b3 in FIG. 7). Accordingly, the second side D2 of the second opening 01 has a plurality of second peaks (c1 to c3 in FIG. 7) and second valleys (d1 to d2 in FIG. 7). The first peaks a1 to a2 of the first side D1 and the second valleys d1 to d3 of the second side D2 are arranged in one-to-one correspondence, and the second peaks c2 to c3 of the second side D2 and the first valleys b1 to b3 of the first side D1 are arranged in one-to-one correspondence. That is, the first peaks of the first side D1 can be engaged into the second valleys on the second side D2, and the second peaks of the second side D2 can be engaged into the first valleys on the first side D1, so that sawtooth shapes of the first side D1 and the second side D2 can be engaged with each other, and the first side D1 and the second side D2 are spaced apart by a certain distance. Specifically, a first valley is formed between two adjacent first peaks and corresponds to a second peak, so that any second peak is located between the first peaks on two sides of the first valley corresponding to the second peak. Any one of the first peaks of the first side D1 is close to a second valley between second peaks of two second sides D2 on two sides of said first peak, with respect to a connection line between the second peaks of the two second sides D2. Likewise, any one of the second peaks on the second side D2 is close to a first valley between first peaks of two first sides D1 on two sides of said second peak, with respect to a connection line between the first peaks of the two first sides D1. Taking the first first peak a1 on the first side D1 in FIG. 7 as an example, the said first peak a1 is disposed corresponding to the first second valley d1 of the second side D2, and a first second peak c1 and a second second peak c2 of the second side D2 are disposed on two sides of the second valley d1, and thus the first second peak c1 and the second second peak c2 are on two sides of the first peak a1. The dotted line in FIG. 7 is a connection line between a vertex of the second peak c1 and a vertex of the second peak c2, and the first peak a1 of the first side D1 is located on a side of the connection line close to the second side D2, that is, the first peak a1 is close to the second valley d1 with respect to the connection line. Therefore, when a stretching force in the first direction S1 (i.e., the upward or downward force in FIG. 7) is applied on the buffer layer 12, the first peak of the first side D1 can abut against the second peaks on two sides of the first peak, and the second peak on the second side D1 can be offset against the first peaks on two sides of the second peak, so that the first opening 01 is prevented from being torn due to excessive deformation in the first direction S1.

In some examples, as shown in FIG. 8, FIG. 8 is a schematic diagram of an exemplary first opening 01 in the buffer layer 12. The first opening 01 may include one third sub-opening 013 and a plurality of fourth sub-openings 014. The third sub-opening 013 extends in a first direction S1, and the plurality of fourth sub-openings 014 extend in a second direction S2 intersecting with the first direction S1. In this embodiment, the following explanation is made taking the case where the first direction S1 is a column direction of sub-pixels, the second direction S2 is a row direction of sub-pixels, and the first direction S1 and the second direction S2 are substantially perpendicular to each other as an example. The plurality of fourth sub-openings 014 are arranged at intervals along an extending direction (the first direction S1) of the third sub-opening 013, and connected to the third sub-opening 013. Taking FIG. 8 as an example, one end of each of the plurality of fourth sub-openings 014 is connected to the third sub-opening 013, while the other end extends in a direction away from the third sub-opening 014. The fourth sub-openings 014 and the third sub-opening 013 form a comb-like first opening 01, and the plurality of fourth sub-openings 014 serve as comb teeth of the comb-like first opening 01. Obviously, the plurality of fourth sub-openings 014 may be connected to the third sub-opening 013 by connecting ends of the fourth sub-openings 014 to the third sub-opening 013, or by making the fourth sub-openings 014 penetrate through the third sub-opening 013, that is, by connecting any part of each fourth sub-opening 014 in the extending direction to the third sub-opening 013, which is not limited herein. There is a partially complete buffer layer 12 between adjacent fourth sub-openings 014, so when the buffer layer 12 is stretched under an external force, the portion between any two adjacent fourth sub-openings 014 of the plurality of fourth sub-openings 014 can provide a certain strength, to prevent excessive deformation of the fourth sub-openings 014 and cracks in the buffer layer 12 thus caused.

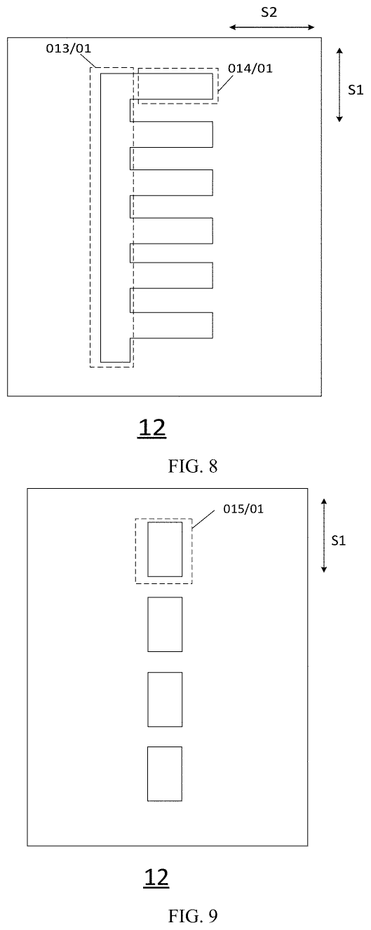

In some examples, as shown in FIG. 9, FIG. 9 is a schematic diagram of an exemplary first opening 01 in the buffer layer 12. The first opening 01 may include a plurality of fifth sub-openings 015 extending in a same direction. In FIG. 9, the case where the plurality of fifth sub-openings 015 extending in the first direction S1 is taken as an example for illustration, and the plurality of fifth sub-openings 015 are arranged in the first direction S1. The shape of the fifth sub-openings 015 is not limited here. The fifth sub-openings 015 may be rectangular, circular or oval openings or the like, and in this embodiment, the fifth sub-openings 015 as rectangular openings is taken are an example for illustration. There is a partially complete buffer layer 12 between adjacent fifth sub-openings 015, so when the buffer layer 12 is stretched under an external force, the portion of the buffer layer 12 between any two adjacent fifth sub-openings 015 of the plurality of fifth sub-openings 015 can provide a certain strength, to prevent excessive deformation of the fifth sub-openings 015 and cracks in the buffer layer 12 thus caused.

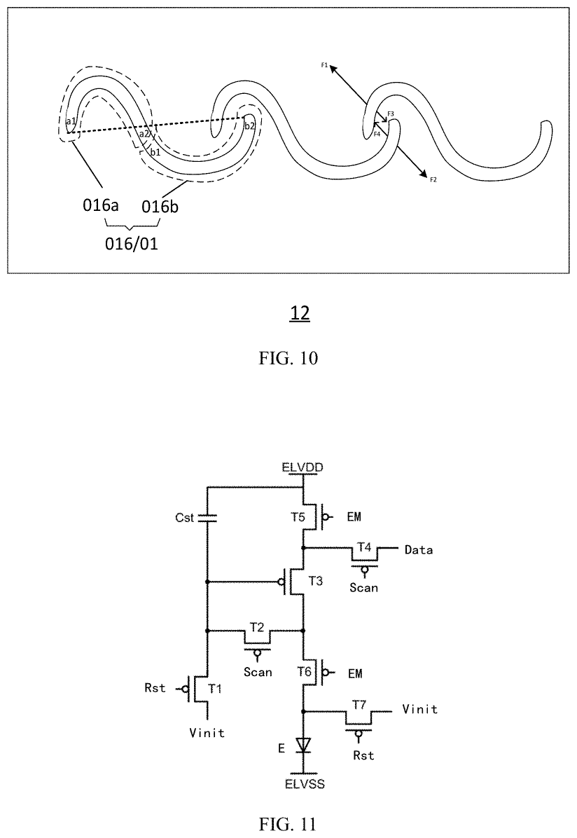

In some examples, as shown in FIG. 10, FIG. 10 is a schematic diagram of an exemplary first opening 01 in the buffer layer 12. The first opening includes a plurality of sixth sub-openings 016, each of which includes a first bent section 016a and a second bent section 016b. The first bent section 016a has a first end a1 and a second end a2, the second bent section 016b has a first end b1 and a second end b2, the second end a2 of the first bent section 016a is connected to the first end b1 of the first bent section 016b, the first bent section 016a and the second bent section 016b are bent in opposite directions so that the sixth sub-openings 016 form an S-like opening. The plurality of sixth sub-openings 016 are arranged in a same direction. In this embodiment, the case where the plurality of sixth sub-openings 016 are arranged in a second direction S2 (a row direction) is taken as an example for illustration. For two adjacent sixth sub-openings 016 among the plurality of sixth sub-openings 016, a connection line between an end of the first bent section 016a and an end of the second bent section 016a of one sixth sub-opening 016 passes through the first bent section 016a of the other sixth sub-opening 016. Taking FIG. 10 as an example, the first sixth sub-opening 016 includes a first bent section 016a and a second bent section 106b. The connection line (shown by the thick dashed lines in FIG. 10) between the first bent section 016a and the second bent section 106b of the first sixth sub-opening 016a passes through the first bent section 016a of the second sixth sub-opening 016a. In other words, two adjacent sixth sub-openings 016 are in a hooked state, and for two adjacent sixth sub-openings 016, an end of the second bent section 016b of a previous sixth sub-opening 016 enters into a bent region of the first bent section 016a of a latter sixth sub-opening 016. Therefore, if the buffer layer 12 is subjected to a stretching force, for example, as shown in FIG. 10, a pulling force F1 and a pulling force F2 which tend to separate the second bent section 016b of the previous sixth sub-opening 016 from the first bent section 016a of the latter sixth sub-opening 016, a pulling force F3 and a pulling force F4 opposite to the pulling force F1 and the pulling force F2 will be generated at a portion of the buffer layer 12 between the second bent section 016b of the previous sixth sub-opening 016 and the first bent section 016a of the latter sixth sub-opening 016, to prevent separation of the second bent section 016b of the previous sixth sub-opening 016 from the first bent section 016a of the latter sixth sub-opening 016, thereby enhancing the tear resistance of the buffer layer 12 and avoiding the problem that cracks are easy to be generated since the buffer layer 12 is relatively weak at the first opening 01 when the buffer layer 12 is provided with the first opening 01, and thus avoiding damage to the buffer layer 12 due to excessive stretching.

It should be noted that the above are merely some exemplary structures of the first opening 01, and the shape of the first opening 01 may include other structures, which is not intended to limit the present disclosure.

In some examples, the display substrate further includes, in addition to the above structures, a plurality of sub-pixels P on the at least one base 1. Specifically, the sub-pixels P are located on a side of the buffer layer 12 of an outermost base 1 of the at least one base 1 away from the sub-base 11, and are merely provided in the island regions Q1. Each sub-pixel P includes a pixel circuit and a light-emitting device, and according to a color of light emitted from the light-emitting device, the sub-pixels P may include multiple types. For example, the light-emitting device may include a red (R) light-emitting device that emits red light, a green (G) light-emitting device that emits green light, and a blue (B) light-emitting device that emits blue light. Therefore, the type of the sub-pixel P may be determined by the type of the light-emitting device constituting the sub-pixel P. Sub-pixels P of different colors constitute a pixel unit. For example, a red sub-pixel, a green sub-pixel and a blue sub-pixel constitute a pixel unit.

In some embodiments, the light-emitting device may be an inorganic light-emitting diode, or an organic light-emitting diode (OLED) fabricated with an organic material, or a micro light-emitting diode (Micro LED) or mini light-emitting diode (mini LED). The Micro LED refers to an ultra-small self-luminous inorganic light-emitting element of a size less than 100 microns without any backlight or filter.

In some examples, the pixel circuit in each sub-pixel P may adopt various structures. For example, the pixel circuit may include a structure of two transistors and one capacitor (2T1C), or a structure of seven transistors and one capacitor (7T1C), or a structure of twelve transistors and one capacitor (12T1C), or the like. As shown in FIG. 11, the pixel circuit including 7T1C is taken as an example. Specifically, the pixel circuit includes a driving transistor T3, a data write transistor T4, a storage capacitor Cst, a threshold compensation transistor T2, a first reset transistor T7, a second reset transistor T1, a first light-emitting control transistor T5, and a second light-emitting control transistor T6. The pixel circuit is configured to drive a light-emitting device E which includes a first electrode, a light-emitting layer and a second electrode sequentially arranged on the base.

For example, as shown in FIG. 11, the data write transistor T4 has a source electrically connected to a source of the driving transistor T3, a drain electrode configured to be electrically connected to a data line Data to receive a data signal, and a gate configured to be electrically connected to a scan signal line to receive a scanning signal Scan. The storage capacitor Cst has a source electrically connected to a first power supply terminal, and a drain electrically connected to a gate of the driving transistor T3. The threshold compensation transistor T2 has a source electrically connected to a drain of the driving transistor T3, a drain electrically connected to the gate of the driving transistor T3, and a gate configured to be electrically connected to a scan signal line to receive a compensation control signal. The second reset transistor T1 has a source configured to be electrically connected a reset power supply terminal to receive a first reset signal Vinit, a drain electrically connected to the gate of the driving transistor T3, and a gate configured to be electrically connected to a reset control signal line to receive a reset control signal Rst. The first reset transistor T7 has a source configured to be electrically connected the reset power supply terminal to receive a reset signal Vinit, a drain electrically connected to a first electrode of a light-emitting device E, and a gate configured to be electrically connected to a reset control signal line to receive a reset control signal Rst. The first light-emitting control transistor T5 has a source electrically connected to the first power supply terminal, a drain electrically connected to the source of the driving transistor T3, and a gate configured to be electrically connected to a light-emitting control signal line to receive a light-emitting control signal EM. The second light-emitting control transistor T6 has a source electrically connected to the drain of the driving transistor T3, a drain electrically connected to the first electrode of the light-emitting device E, and a gate configured to be electrically connected to a light-emitting control signal line to receive a light-emitting control signal EM. A second electrode of the light-emitting device E is electrically connected to a second power supply terminal (for outputting a second supply voltage ELVSS).

For example, one of the first power supply terminal and the second power supply terminal is a high voltage terminal, while the other is a low voltage terminal. For example, the first power supply terminal is a voltage source configured to output a constant first voltage ELVDD which is a positive voltage; and the second power supply terminal may be a voltage source configured to output a constant second voltage ELVSS which is a negative voltage, and so on. For example, in some examples, the second power supply terminal may be grounded.

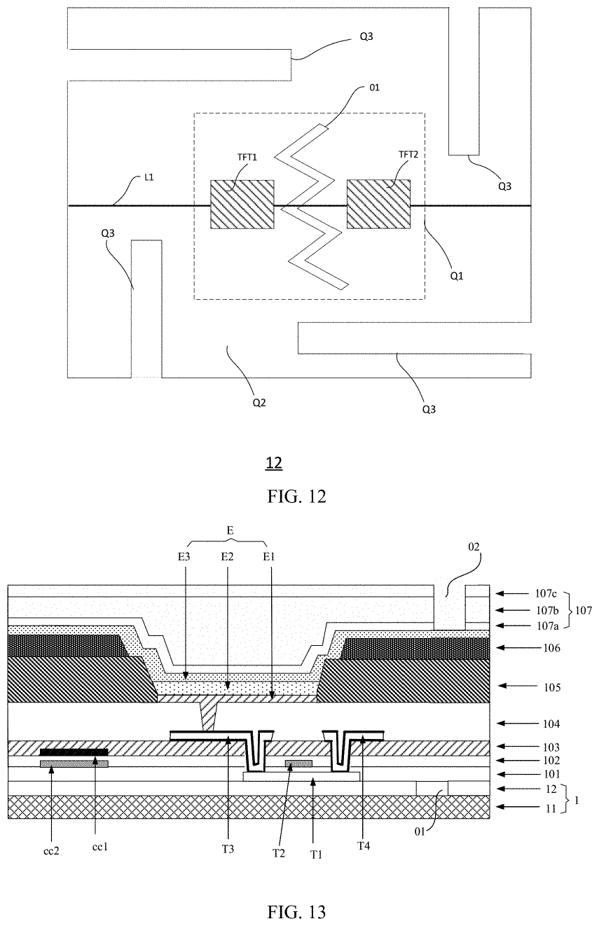

In some examples, the sub-pixels P are located on a side of the buffer layer 12 of an outermost base 1 of the at least one base 1 away from the sub-base 11. Each sub-pixel P includes a pixel circuit and a light-emitting device. The pixel circuits include a plurality of transistors, and orthographic projections of the plurality of transistors on the buffer layer 12 do not overlap the first opening 01 in the buffer layer 12. For example, referring to FIG. 12, taking the pixel circuit including a first transistor TFT1 (e.g., a switch transistor) and a second transistor TFT2 (e.g., a driving transistor) as an example, a gate line L1 is connected between the first transistor TFT1 and the second transistor TFT2, the first opening 01 in the buffer layer 12 is provided between the first transistor TFT1 and the second transistor TFT2, and orthographic projections of the first transistor TFT1 and the second transistor TFT2 on the buffer layer do not overlap the first opening 01. Therefore, deformation of the first opening 01 in the buffer layer 12 will not affect the working performance of each transistor in the pixel circuit. Obviously, under certain conditions, the transistors in the pixel circuit may also be disposed on the first opening 01. For example, under the condition that deformation of the first opening 01 is less than 0.5% of an opening width of the first opening 01, the transistors may be disposed right above the first opening 01. The specific setting may be set as required, which is not limited here.

Further, taking an exemplary display substrate as an example, the display substrate further includes a plurality of signal lines, which are distributed in the bridge regions Q2 and extend from the bridge regions Q2 to the island regions Q1 to connect the transistors in the pixel circuit. Specifically, the plurality of signal lines may include a plurality of scan signal lines, a plurality of data lines, a plurality of reset signal lines, a plurality of supply voltage lines, a plurality of light-emitting control signal lines, and a plurality of initialization power supply signal lines (none of which are shown in the figures). The data lines and supply voltage lines extend in a column direction of the sub-pixels P arranged in an array, and the plurality of scan signal lines, reset signal lines, light-emitting control signal lines, and initialization power supply signal lines are arranged in a row direction of the sub-pixels P arranged in an array. Each data line is connected to a column of sub-pixels P, and provides a data voltage Data for the pixel circuits of the column of sub-pixels P. Each supply voltage line is connected to a column of sub-pixels P and to the first supply voltage terminal, and provides a first supply voltage ELVDD for the pixel circuits of the column of sub-pixels P. Each scan signal line is connected to a row of sub-pixels P, and provides a scanning signal Scan for the row of sub-pixels P. Each light-emitting control signal line is connected to a row of sub-pixels P, and provides a light-emitting control signal EM for the row of sub-pixels P. Each reset signal line is connected to a row of sub-pixels P, and provides a reset control signal Rst for the row of sub-pixels P. Each initialization power supply signal lines is connected to a row of sub-pixels P and to an initialization signal terminal, and provides an initialization signal Vinit for the row of sub-pixels P. Obviously, the structure of the display panel is not limited thereto, and the signal lines included in the display panel and the arrangement of the signal lines are not limited thereto. The above display panel is merely taken as an example for illustration, and does not constitute any limitation to the present disclosure.

It is possible that all the thin film transistors in the pixel circuit are top-gate thin film transistors, or bottom-gate thin film transistors. Obviously, it is also possible that one part of the thin film transistors are top gate type thin film transistors, and the other part are bottom gate type thin film transistors. In the following description, only the case where all the driving transistors in the pixel circuit are top gate type thin film transistors is taken as an example for illustration. In order to clarify the relationship between the pixel circuit and each film layer of the light-emitting device E in the embodiments of the present disclosure, referring to FIG. 13, illustration will be made in combination with the sectional view of a driving transistor and a light-emitting device in an arbitrary pixel circuit of the display substrate shown in FIG. 1. It should be noted that FIG. 13 merely shows a sectional view of a pixel circuit provided in an island region Q1.

As shown in FIG. 13, a case where the display substrate is a single-layer base 1 including a layer of sub-base 11 and a buffer layer 12 on the sub-base 11 is taken as an example for illustration. The driving transistor may be a top-gate thin film transistor, including an active layer T1, a first gate insulation layer 101, a gate T2, a second gate insulation layer 102, an interlayer dielectric layer 103, a source T4, and a drain T3. Specifically, the active layer T1 may be formed on the buffer layer 12, the first gate insulation layer 101 covers the buffer layer 12 and the active layer T1, the gate T2 is formed on a side of the first gate insulation layer 101 facing away from the active layer T1, the second gate insulation layer 102 covers the gate T2 and the first gate insulation layer 101, the interlayer dielectric layer 103 covers the second gate insulation layer 102, the source T4 and the drain T3 are formed on a side of the interlayer dielectric layer 103 facing away from the base 1 and respectively located on two opposite sides of the gate T2, and the source T4 and the drain T3 may respectively contact two opposite sides of the active layer T1 through via holes.

As shown in FIG. 13, a capacitor structure (e.g., the storage capacitor in the pixel circuit) may include a first electrode plate cc1 and a second electrode plate cc2. The second electrode plate cc2 is disposed in a same layer as the gate T2, and the first electrode plate cc1 is disposed between the second gate insulation layer 102 and the interlayer dielectric layer 103 and opposite to the second electrode plate cc2.

For example, the gate T2, the first electrode plate cc1 and the second electrode plate cc2 may be made of a metal material or an alloy material, for example, may include molybdenum, aluminum, titanium, and the like. The source T4 and the drain T3 may include a metal material or an alloy material, such as a metal single-layer or a multi-layer structure formed of molybdenum, aluminum, titanium, and the like. For example, the multi-layer structure is a multi-metal layer stack, such as a three-layer metal stack of aluminum, titanium and aluminum (Al/Ti/Al), or the like.

As shown in FIG. 13, the light-emitting device E is located in the island region Q1, and the light-emitting device E may include a first electrode E1 and a pixel defining layer 105 sequentially formed on the interlayer dielectric layer 103. It will be appreciated that the light-emitting device E may further include a light-emitting layer E2 and a second electrode E3.

In detail, when the thin film transistor on the display substrate is a top gate type transistor, a planarization layer 104 may be formed before manufacturing the light-emitting device E, and the planarization layer 104 may have a single-layer structure or a multi-layer structure. The planarization layer 104 is typically made of an organic material, such as a photoresist, an acrylic-based polymer, a silicon-based polymer, or the like. As shown in FIG. 13, the first electrode E1 of the light-emitting device E may be connected to the drain T3 of the driving transistor through a via hole penetrating through the planarization layer 104, and the first electrode E1 may be an anode made of a material including ITO (indium tin oxide), indium zinc oxide (IZO), zinc oxide (ZnO), or the like. A material of the pixel defining layer 105 includes, but is not limited to, an organic material such as photoresist, and a portion of the pixel defining layer located in the display area may have a pixel opening from which the first electrode E1 is exposed. The light-emitting layer E2 is located in the pixel opening and formed on the first electrode E1. The light-emitting layer E2 may include a small molecule organic material or a polymer molecule organic material, which may be a fluorescent light-emitting material or a phosphorescent light-emitting material that can emit red light, green light, blue light, or white light, or the like. In addition, according to different practical needs and in different examples, the light-emitting layer E2 may further include an electron injection layer, an electron transport layer, a hole injection layer, a hole transport layer or other functional layers; the second electrode E3 covers the light-emitting layer, and the second electrode E3 has a polarity opposite to the first electrode; and the second electrode may be a cathode made of a metal material such as lithium (Li), aluminum (Al), magnesium (Mg), silver (Ag), etc.

It should be noted that, as shown in FIG. 13, the first electrode E1, the light-emitting layer E2, and the second electrode E3 may constitute a light-emitting device E. In addition, it should be noted that the first electrodes E1 of respective light-emitting devices E are independent of each other, and the second electrodes E3 of respective light-emitting devices E are connected over an entire surface. That is, the second electrodes E3 are formed to have a full-surface structure on the display substrate, and serves as a common electrode for a plurality of light-emitting devices 1d.

In some embodiments, as shown in FIG. 6, a support portion 106 may be further provided on a side of the pixel defining layer 105 facing away from the interlayer dielectric layer 103, and the support portion 106 may function to support a protective film layer (not shown) to prevent the protective film layer from contacting the first electrode E1 or other wires to damage the first electrode E1 or other wires. It should be noted that the protective film layer is mainly provided during transfer of semi-finished products to avoid damages to the semi-finished products during the transfer. Specifically, a coverage protective film layer may be provided in the process of transferring a substrate on which the support portion 106 is formed to an evaporation line, and the protective film layer may be removed before evaporation of the light-emitting material.

For example, the support portion 106 may be made of the same material as the pixel defining layer 105, and the support portion 106 and the pixel defining layer 105 may be formed in a same patterning process. However, the present disclosure is not limited thereto, and the support portion 106 may be made of a different material, and formed in a different patterning process, from the pixel defining layer 105.

In some examples, at least one inorganic film layer is provided on the buffer layer 12 of the outermost base 1 of the bases 1 of the display substrate, the at least one inorganic film layer is laminated with the buffer layer 12 of the outermost base 1 of the at least one base 1, and the at least one inorganic film layer has at least one second opening 02 is provided at a position of the at least one inorganic film layer corresponding to each island region Q1. Among the multiple film layers of the display substrate, the inorganic film layers typically have a larger coverage area, and are stacked at edges of the island regions Q1. During preparation of the display substrate, each film layer is made by a laser lift off process. Taking the process of forming the buffer layer 12 on the sub-base 11 as an example, firstly, a photoresist is coated on the sub-base 11, patterned, developed, and exposed to be removed. Then, a film is formed on the photoresist to form a film layer of the buffer layer 12. Finally, the remaining photoresist and the buffer layer 12 on the photoresist are peeled off together, and the film layer of the buffer layer 12 left on the sub-base 11 is the film pattern of the buffer layer 12. In the step of peeling off the photoresist, a stretching force from the sub-base 11 to the buffer layer 12 will be applied to the buffer layer 12. During stretching of the buffer layer 12, cracks are easy to be generated due to a low strength at the first opening 01.

In order to solve the above problem, a second opening 02 may be further provided in the inorganic film layer of the buffer layer 12. The above-mentioned inorganic film layer may be any inorganic film layer of the film layers of the display substrate. For example, referring to FIG. 13, taking the inorganic film layer as an encapsulation layer 107 as an example, the display substrate further includes an encapsulation layer 107. The encapsulation layer 107 is disposed on a side of the light-emitting device E of the sub-pixel facing away from the base 1, and configured to isolate external water and oxygen. The encapsulation layer 107 includes a first inorganic encapsulation thin film layer 117a, an organic encapsulation thin film layer 117b, and a second inorganic encapsulation thin film layer 117c sequentially stacked. The first inorganic encapsulation thin film layer 117a and the second inorganic encapsulation thin film layer 117c may be made of an inorganic material such as silicon nitride, silicon oxide, or the like. The organic encapsulation thin film layer 117b is configured to implement planarization to facilitate manufacture of the second inorganic encapsulation thin film layer 117c, and the organic encapsulation thin film layer 117b may be made of a material including an acrylic-based polymer, a silicon-based polymer, or the like. The encapsulation layer 107 has at least one second opening 02, and the encapsulation layer 107 covers and seals the entire light-emitting device E. Therefore, the encapsulation layer 107 may directly overlap the base 1 in a peripheral region of the light-emitting device E.

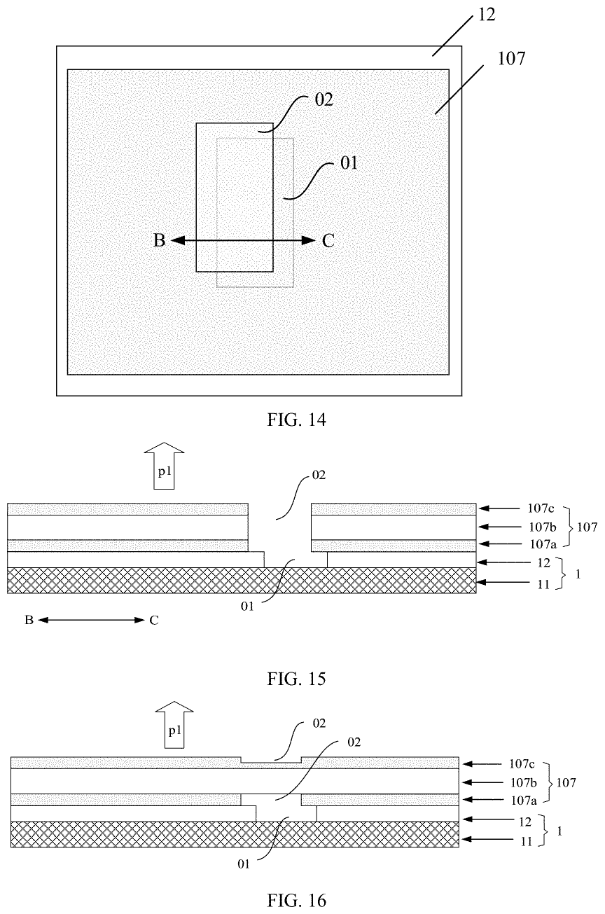

Specifically, referring to FIGS. 14 to 16, the inorganic film layer being an encapsulation layer 107 in the peripheral region of the light-emitting device E is taken as an example for illustration. It will be appreciated that the inorganic film layer of the display substrate is not limited to the encapsulation layer 107. The encapsulation layer 107 is disposed on a side of the buffer layer 12 facing away from the sub-base 11 and overlaps the buffer layer 12. The encapsulation layer 107 has at least one second opening 02. Referring to FIG. 14, which shows a positional relationship between the second opening 02 in the encapsulation layer 107 and the first opening 01 in the buffer layer 12, specifically, an orthographic projection of the second opening 02 in the encapsulation layer 107 on the buffer layer 12 has an overlap region with the first opening 01 in the buffer layer 12. Referring to FIG. 15, which is a sectional view of the base 1 and the encapsulation layer 107 taken along line B-C of FIG. 14, in the process of preparing the encapsulation layer 107 by laser lift off, after the encapsulation layer 107 is patterned, a stretching force (as indicated by P1) from the sub-base 11 to the buffer layer 12 will be applied to the buffer layer 12 in the step of peeling off the photoresist. During stretching of the buffer layer 12, since the second opening 02 is provided at a position on the encapsulation layer 107 of the buffer layer 12 corresponding to the first opening 01, the film strength of the encapsulation layer 107 at the second opening 02 is greatly reduced due to the existence of the second opening 02. Therefore, the stretching force on the buffer layer 12 is reduced, thereby effectively avoiding cracks generated in the buffer layer 12 during the stretching. Further, the film structure of the encapsulation layer 107 around the second opening 02 will interact with the film structure of the buffer layer 12 around the first opening 01 to form a reinforced structure, thereby further avoiding cracks generated in the buffer layer 12 during the stretching and effectively enhancing the tear resistance of the buffer layer 12.

In some examples, as shown in FIG. 16, the encapsulation layer 107 includes an inorganic encapsulation thin film layer and an organic encapsulation thin film layer sequentially stacked. Taking the encapsulation layer 107 including a first inorganic encapsulation thin film layer 117a, an organic encapsulation thin film layer 117b, and a second inorganic encapsulation thin film layer 117c as an example, the second opening 02 in the encapsulation layer 107 may be provided on the first inorganic encapsulation thin film layer 117a, the organic encapsulation thin film layer 117b, and a second inorganic encapsulation thin film layer 117c, or may be provided on only the first inorganic encapsulation thin film layer 117a and the second inorganic encapsulation thin film layer 117c (as shown in FIG. 16). Since the organic encapsulation film layer 117b is made of an organic material and has a low hardness, the stress generated under stretching is relatively small, and thus the opening may be omitted.

In some examples, the second opening 02 in inorganic film layer and the first opening 01 in the buffer layer 12 are provided in one-to-one correspondence, and have a same shape. In other words, the number of first openings 01 in the buffer layer 12 is the same as the number of second openings 02 in the inorganic film layer, and positions of the first openings 01 in the buffer layer 12 is substantially the same as positions of the second openings in the inorganic film layer.

In some examples, referring to FIG. 16, similar to the depth of the first opening 01, each second opening 02 in the inorganic film layer may penetrate through the inorganic film layer corresponding to the second opening, as shown by the second openings 02 in the first inorganic thin film encapsulation layer 117a in FIG. 16, or each second opening 02 in the inorganic film layer may have a depth less than the inorganic film layer corresponding to the second opening, as shown by the second opening 02 in the second inorganic thin film encapsulation layer 117c in FIG. 16, and specifically, may be less than half of a thickness of the inorganic film layer. Therefore, it can ensure that the second opening 02 in the inorganic film layer will not be excessively deformed when the display substrate is stretched, and a bottom of the film layer of the inorganic film layer at the second opening 02 can provide extra strength to the inorganic film layer, thereby avoiding tearing of the inorganic film layer due to excessive deformation of the second opening 02.

In a second aspect, an embodiment of the present disclosure further provides a display apparatus including the display substrate as described above. It should be noted that the display apparatus provided in this embodiment may be: a mobile phone, a tablet PC, a television, a monitor, a notebook computer, a digital album, a GPS or any other product or component having a display function. Other essential components of the display apparatus are regarded as present by one of ordinary skill in the art, which are not described herein and should not be construed as limiting the present disclosure.

Further, the display apparatus may include various types of display devices, such as a liquid crystal display device, an OLED display device, a Mini LED display device, or the like, which is not limited herein.

It will be appreciated that the above implementations are merely exemplary implementations for the purpose of illustrating the principle of the present disclosure, and the present disclosure is not limited thereto. It will be apparent to one of ordinary skill in the art that various modifications and variations can be made to the present disclosure without departing from the spirit or essence of the present disclosure. Such modifications and variations should also be considered as falling into the protection scope of the present disclosure.

1. A display substrate having a plurality of island regions, bridge regions and clearance regions, the bridge regions being disposed around the island regions, the display substrate comprising:
at least one base, the base comprising a sub-base and a buffer layer, wherein the sub-base comprises a first surface and a second surface opposite to each other, and the buffer layer is disposed on a side of the second surface of the sub-base away from the first surface; and in the at least one base, the sub-base of any base has a same orientation;
a plurality of sub-pixels on a side of the buffer layer of an outermost base of the at least one base away from the sub-base of the outermost base, each sub-pixel comprising a light-emitting device and a pixel circuit, wherein each island region is provided with at least one of the sub-pixels; and
a plurality of signal lines connected to the pixel circuit, wherein the plurality of signal lines are distributed in the bridge regions;
wherein
the buffer layer of the at least one base has at least one first opening provided at a position of the buffer layer corresponding to the island region.

2. The display substrate according to claim 1, wherein the first opening comprises a plurality of first sub-openings and a plurality of second sub-openings arranged at intervals along a first direction, and
wherein an extending direction of the plurality of first sub-openings intersects with an extending direction of the plurality of second sub-openings.

3. The display substrate according to claim 2, wherein the plurality of first sub-openings are connected to the plurality of second sub-openings to form the first opening, and the first opening has a first side and a second side opposite to each other in the first direction,
the first side has a plurality of first peaks and a plurality of first valleys; and the second side has a plurality of second peaks and a plurality of second valleys, wherein
the first peaks and the second valleys are arranged in one-to-one correspondence, and the second peaks and the first valleys are arranged in one-to-one correspondence, and
any one of the first peaks is close to a second valley between two second peaks on two sides of the first peak, with respect to a connection line between the two second peaks.

4. The display substrate according to claim 1, wherein the first opening comprises one third sub-opening and a plurality of fourth sub-openings, the third sub-opening extends in a first direction, and the plurality of fourth sub-openings extend in a second direction intersecting with the first direction, and wherein
the plurality of fourth sub-openings are connected to the third sub-opening, and arranged in the first direction.

5. The display substrate according to claim 1, wherein the first opening comprises a plurality of fifth sub-openings extending in a same direction and arranged in a first direction.

6. The display substrate according to claim 1, wherein the first opening comprises a plurality of sixth sub-openings, each of which comprises a first bent section and a second bent section bent in opposite directions, and a second end of the first bent section is connected to the first end of the first bent section; wherein
for two adjacent sixth sub-openings of the sixth sub-openings, a connection line between an end of the first bent section and an end of the second bent section of one sixth sub-opening among the two adjacent sixth sub-openings passes through the first bent section of another sixth sub-opening among the two adjacent sixth sub-openings.

7. The display substrate according to claim 1, wherein the pixel circuits comprise a plurality of transistors, and orthographic projections of the plurality of transistors on the buffer layer do not overlap the first opening.

8. The display substrate according to claim 1, wherein the first opening penetrates a corresponding buffer layer.

9. The display substrate according to claim 1, further comprising: at least one inorganic film layer laminated with the buffer layer of the outermost base of the at least one base, wherein the at least one inorganic film layer has at least one second opening provided at a position of the at least one inorganic film layer corresponding to the island region.

10. The display substrate according to claim 9, wherein an orthographic projection of the second opening on the buffer layer has an overlap region with the first opening.

11. The display substrate according to claim 10, wherein the second opening and the first opening are provided in one-to-one correspondence, and have a same shape.

12. The display substrate according to claim 10, wherein the second opening penetrates a corresponding inorganic film layer.

13. The display substrate according to claim 1, wherein the sub-base of any one of the at least one base is a flexible base; the at least one base comprises a first base and a second base, the first base comprises a first sub-base and a first buffer layer, and the second base comprises a second sub-base and a second buffer layer; and wherein
a thickness of the second sub-base is 40% to 60% of a thickness of the first sub-base.

14. The display substrate according to claim 1, wherein the base is a rigid base having corner regions, and the island regions, the bridge regions and the clearance regions are provided in only the corner regions.

15. A display apparatus, comprising the display substrate according to claim 1.

16. The display substrate according to claim 1, wherein the first opening has a depth less than half a thickness of the corresponding buffer layer.

17. The display substrate according to claim 10, wherein the second opening has a depth less than half a thickness of the corresponding inorganic film layer.
